(19) United States
(12) Patent Application Publication
(10) Pub. No.: US 2026/0206185 A1
(43) Pub. Date: Jul. 16, 2026

(54) STAND-OFF FOR HEATSINK DETECTION

(71) Applicant: Dell Products L.P., Round Rock, TX (US)

(72) Inventors: Kang-Wei Fan, Taoyuan City (TW); Shang-Ting Qiu, Taipei City (TW); Po-I Huang, New Taipei City (TW)

(73) Assignee: Dell Products L.P., Round Rock, TX (US)

(21) Appl. No.: 19/019,009

(22) Filed: Jan. 13, 2025

(51) Int. Cl. H05K 7/20; F28F 9/00; G06F 1/20

(52) U.S. Cl. CPC H05K 7/2039; F28F 9/005; G06F 1/20

(57) ABSTRACT

Stand-off systems and methods for heatsink detection are described. In an illustrative, non-limiting embodiment, an assembly may include: a stand-off configured to receive an Information Handling System (IHS) component; and a bracket configured to close an electrical circuit via the stand-off, where the electrical circuit is usable to determine whether a heatsink is present. In another illustrative, non-limiting embodiment, a stand-off may include: an inner conductive ring configured to receive a fastener that couples an IHS component to the stand-off; an insulation ring coupled to the inner conductive ring; and an outer conductive ring coupled to the insulation ring, the outer conductive ring coupled to a conductive bracket configured to close an electrical circuit between the inner conductive ring and the outer conductive ring to indicate the presence of a heatsink.

### FIELD

This disclosure relates generally to Information Handling Systems (IHSs), and more specifically, to stand-off systems and methods for heatsink detection.

### BACKGROUND

As the value and use of information continues to increase, individuals and businesses seek additional ways to process and store it. One option available to users is an Information Handling System (IHS). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated.

Variations in IHSs allow for IHSs to be general or configured for a specific user or specific use, such as financial transaction processing, airline reservations, enterprise data storage, or global communications. In addition, IHSs may include a variety of hardware and software components that may be configured to process, store, and communicate information and may include one or more computer systems, data storage systems, and networking systems.

### SUMMARY

Stand-off systems and methods for heatsink detection are described. In an illustrative, non-limiting embodiment, an assembly may include: a stand-off configured to receive an Information Handling System (IHS) component; and a bracket configured to close an electrical circuit via the stand-off, where the electrical circuit is usable to determine whether a heatsink is present.

The component may include a device disposed on a Printed Circuit Board (PCB) and the PCB is mountable on the stand-off. The device may include at least one of: a processor, a memory, a storage device, a system-on-chip (SoC), a fan, a battery, or a power supply.

In some implementations, the stand-off may include: an inner conductive ring; an insulation ring having an inner surface coupled to an outer surface of the inner conductive ring; and an outer conductive ring having an inner surface coupled to an outer surface of the insulation ring.

To close an electrical circuit, the bracket may electrically couple the inner conductive ring to the outer conductive ring. The inner conductive ring may be coupled to a ground terminal, and the outer conductive ring may be coupled to a General Purpose Input/Output (GPIO) pin of an Embedded Controller (EC), Baseboard Management Controller (BMC), or Chassis Management Controller (CMC).

The outer conductive ring and the insulation ring may form a sleeve that screws onto the inner conductive ring. The bracket may electrically couple the inner ring to the outer ring via a fastener, the fastener configured to mechanically couple the component to the stand-off. The inner conductive ring may be taller than the outer conductive ring.

The inner conductive ring may include a first portion having a first height and a second portion having a second height smaller than the first height, where the insulation ring has the second height and the outer conductive ring has a third height smaller than the second height. The bracket may be configured to apply pressure against the outer conductive ring. An edge of the bracket may be chamfered to match an edge of the outer conductive ring.

A stand-off, may include an inner conductive ring configured to receive a fastener that couples an IHS component to the stand-off; an insulation ring coupled to the inner conductive ring; and an outer conductive ring coupled to the insulation ring, the outer conductive ring coupled to a conductive bracket configured to close an electrical circuit between the inner conductive ring and the outer conductive ring to indicate the presence of a heatsink.

The outer conductive ring and the insulation ring may form a sleeve that screws onto the inner conductive ring. The inner conductive ring may be taller than the outer conductive ring. The inner conductive ring may include a first portion having a first height and a second portion having a second height smaller than the first height, and the outer conductive ring may have a third height smaller than the second height. The bracket may be configured to apply a force against the outer conductive ring. Moreover, an edge of outer conductive ring may be chamfered to match an edge of the bracket.

In yet another illustrative, non-limiting embodiment, a method may include: transmitting a signal via a GPIO pin to a stand-off of an IHS, wherein the stand-off enables an IHS component to be fastened onto the IHS; and determining whether a heatsink is coupled to the IHS component based, at least in part, upon whether a bracket closes an electrical circuit provided by the stand-off. The stand-off may include an inner conductive ring, an insulation ring coupled to the inner conductive ring, and an outer conductive ring coupled to the insulation ring, and where to close the electrical circuit, the bracket couples the inner ring to the outer ring.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity, and have not necessarily been drawn to scale.

FIG. 1 is a diagram illustrating examples of components of an Information Handling System (IHS), according to some embodiments.

FIG. 2 is a diagram illustrating an example of a stand-off system for heatsink detection, according to various embodiments.

FIG. 3 is a diagram illustrating an example of a stand-off, according to various embodiments.

FIG. 4 is an exploded view of the stand-off, according to various embodiments.

FIG. 5 is a cross-sectional view of the stand-off in an IHS chassis or motherboard, according to various embodiments.

FIG. 6 is a diagram illustrating an example of another stand-off, according to various embodiments.

FIG. 7 is an exploded view of the other stand-off, according to various embodiments.

FIG. 8 is a cross-sectional view of the other stand-off in an IHS chassis or motherboard, according to various embodiments.

FIG. 9 is a diagram of an example of a stand-off configured to receive an IHS component, according to some embodiments.

FIG. 10 is a diagram of an example of an IHS component fastened onto the stand-off without a heatsink, according to some embodiments.

FIG. 11 is a cross-section of the IHS component fastened onto the stand-off without a heatsink, according to some embodiments.

FIG. 12 is a diagram of an example of an IHS component and heatsink fastened onto the stand-off, according to some embodiments.

FIG. 13 is a diagram of an IHS component and heatsink being coupled to the stand-off, according to some embodiments.

FIG. 14 is a cross-section of the IHS component and heatsink fastened onto the stand-off, according to some embodiments.

FIG. 15 is a cross-section of a bracket coupled to an outer conductive ring of the stand-off, according to some embodiments.

### DETAILED DESCRIPTION

Heatsinks are commonly used to dissipate heat from components such as Solid-State Drives (SSDs) to ensure adequate cooling and prevent components from exceeding temperature thresholds in Information Handling Systems (IHSs). Overheating can lead to system instability or damage to the components. The failure to install a heatsink when adding a new SSD module, for example, to the system can result in SSD overheating and performance degradation.

Conventional solutions for detecting the presence of a heatsink rely on two connection points on the motherboard or Printed Circuit Board (PCB) to close an electrical loop. This approach consumes additional space on the PCB. Alternatively, systems without detection capabilities require on-site reviews to verify whether an SSD heatsink has been installed, which can be time-consuming and inefficient.

To address these, and other concerns, stand-off systems and methods for heatsink detection described herein may separate the stand-off into two portions: an inner connective nut or ring and an outer connective nut or ring, with an insulating material in between to block a direct connection between the inner and outer rings. The inner conductive ring may be coupled to a ground terminal, and the outer connective ring may be configured to receive signal from a General-Purpose Input/Output (GPIO) pin of an Embedded Controller (EC), Baseboard Management Controller (BMC), or Chassis Management Controller (CMC).

When the heatsink bridges the connection between the inner and outer conductive rings, for example, via a conductive bracket or the like, the electrical circuit between the rings closes, thus sending a notification to EC, BMC, or CMC about the presence of the heatsink. In various implementations, this design may reduce the need for additional space on the motherboard and allow for remote detection of the heatsink, thereby improving IHS reliability and reducing debugging time.

For purposes of this disclosure, an Information Handling System (IHS) may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), network storage device, or any other suitable device and may vary in size, shape, performance, functionality, and price.

An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various Input/Output (I/O) devices, such as a keyboard, a mouse, touch screen, and/or a video display. An IHS may also include one or more buses operable to transmit communications between the various hardware components.

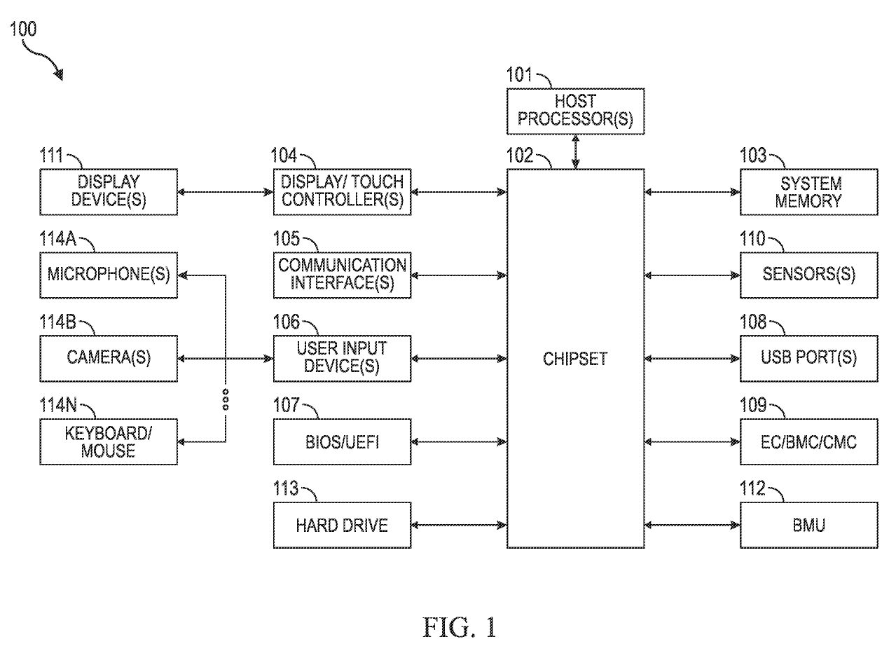

FIG. 1 is a diagram illustrating examples of components of IHS 100 configured according to some embodiments. As shown, IHS 100 includes host processor(s) 101. In various embodiments, IHS 100 may be a single-processor system, a multi-processor system including two or more processors and/or processor cores. Host processor(s) 101 may include any processor capable of executing program instructions, such as a PENTIUM processor, or any general-purpose or embedded processor implementing any of a variety of Instruction Set Architectures (ISAs), such as an x86 or a Reduced Instruction Set Computer (RISC) ISA (e.g., POWERPC, ARM, SPARC, MIPS, etc.).

IHS 100 utilizes a chipset 102 that may include one or more integrated circuits that are connected to processor(s) 101. In the embodiment of FIG. 1, processor(s) 101 is depicted as a separate component from chipset 102. In other embodiments, chipset 102, or portions of chipset 102 may be implemented directly within the integrated circuitry of processor(s) 101. Chipset 102 provides processor(s) 101 with access to a variety of resources of the IHS.

In some embodiments, processor(s) 101 may include an integrated memory controller that may be implemented directly within the circuitry of processor(s) 101, or the memory controller may be a separate integrated circuit that is located on the same die as processor(s) 101. The memory controller may be configured to manage the transfer of data to and from system memory 103 of IHS 100 via a high-speed memory interface. System memory 103 provides processor(s) 101 with a high-speed memory that may be used in the execution of computer program instructions by processor(s) 101.

Accordingly, system memory 103 may include memory components, such as static RAM (SRAM), dynamic RAM (DRAM), NAND Flash memory, suitable for supporting high-speed memory operations by processor(s). In certain embodiments, system memory 103 may combine both persistent, non-volatile memory and volatile memory. In certain embodiments, system memory 103 may be comprised of multiple removable memory modules.

As illustrated, a variety of resources may be coupled to processor(s) 101 through chipset 102. For instance, chipset 102 may be coupled to a wireless network controller 105 that may support different types of wireless network connectivity. In certain embodiments, wireless network controller 105 may include one or more Network Interface Controllers (NICs). For example, wireless network controller 105 may implement hardware for communicating via specific networking technology, such as Wi-Fi, BLUETOOTH, and mobile cellular networks (e.g., CDMA, TDMA, LTE). In some embodiments, network controller 105 may support wireless Wi-Fi communications, and may include a Wi-Fi controller or wireless NIC card by which IHS 100 transmits and receives wireless Wi-Fi signals. In some embodiments, the wireless signaling utilized by wireless network controller 105 may be implemented using multiple wireless antenna 105a.

Chipset 102 also provides processor(s) 101 with access to one or more storage drives 113. In various embodiments, storage drives 113 may be integral to IHS 100 or may be external to IHS 100. In some embodiments, storage drive(s) 113 may be accessed via a storage controller that may be an integrated component of the storage device. For example, a storage controller may be a system-on-chip function of processor(s) 101. Meanwhile, storage drive(s) 113 may be implemented using any memory technology allowing IHS 100 to store and retrieve data. For instance, storage drive(s) 113 may be a magnetic hard disk storage drive or a solid-state storage drive. In certain embodiments, storage drive(s) 113 may include a system of storage devices, such as a cloud drive accessible via network interface 105.

As illustrated, IHS 100 also includes BIOS (Basic Input/Output System) 107 that may be stored in a non-volatile memory accessible by chipset 102. In various embodiments, BIOS 107 may be implemented using a dedicated microcontroller coupled to the motherboard of IHS 100. In some cases, BIOS 107 may be implemented as operations of EC/BMC/CMC 109. Upon powering or restarting IHS 100, processor(s) 101 may utilize BIOS 107 instructions to initialize and test hardware components coupled to IHS 100.

BIOS 107 instructions may also load a host Operating System (OS) for use by IHS 100. BIOS 107 provides an abstraction layer that allows the OS to interface with certain hardware components of IHS 100. The Unified Extensible Firmware Interface (UEFI) was designed as a successor to BIOS. As a result, many IHSs utilize UEFI in addition to or instead of a BIOS. As used herein, BIOS is intended to also encompass UEFI.

As described, one or more display device(s) 111 may be coupled to IHS 100. Display device(s) 111 may include a plurality of pixels that are arranged in a matrix and are configured to display visual information. Display device(s) 111 may include Liquid Crystal Display (LCD), Light Emitting Diode (LED), organic LED (OLED), or other thin film display technologies.

In some embodiments, display device(s) 111 may be capable of receiving touch inputs from a user. In some embodiments, these touch inputs received via display device(s) 111 may be processed by a touch controller that may be separate from other controllers used to display content. In some embodiments, the touch controller functions may be implemented by a display controller.

Chipset 102 may operate one or more display device(s) 111 via graphics processor and/or Graphics Processor Unit (GPU) 104. In some embodiments, graphics processor 104 may be disposed within a video or graphics card or within an embedded controller installed in IHS 100. For instance, graphics processor 104 may be integrated within processor(s) 101, such as a component of a system-on-chip.

In some cases, IHS 100 may utilize EC, BMC, or CMC 109. In certain embodiments, EC/BMC/CMC 109 may operate from a separate power plane from processor(s) 101. Firmware instructions utilized by EC/BMC/CMC 109 may be used to operate a secure execution environment that may include operations for providing various core functions of IHS 100, such as power management and management of certain operating modes of IHS 100.

For instance, EC/BMC/CMC 109 may implement operations for interfacing with a power supply unit (PSU) 112 in managing power for IHS 100. In certain instances, EC/BMC/CMC 109 may be configured to set and/or enforce input current limits, current sharing ratios, load balancing parameters, etc. with respect to PSU 112 and/or other PSUs.

In various embodiments, EC/BMC/CMC 109 may include General Purpose Input/Output (GPIO) pins that can be configured to perform various input or output functions. Generally, GPIO pins may be used by EC/BMC/CMC 109 to interface with various components and sensors within IHS 100. Moreover, as discussed in more detail below, a GPIO pin may be used to detect the presence of a heatsink by monitoring the electrical connection between inner and outer conductive rings of a stand-off. When the heatsink is installed, it bridges the connection between the inner and outer rings, closing the electrical circuit and sending a signal to the GPIO pin. This signal can then be processed by the EC/BMC/CMC 109 to determine the presence of the heatsink and take appropriate actions, such as adjusting power management settings or generating alerts.

IHS 100 may include a wide variety of sensors 110 for use in gathering telemetry data that can be used in the management of the IHS’s operations. Sensors 110 may be disposed on or within the chassis of IHS 100, and may include, but are not limited to: current, voltage, power, magnetic, radio, optical (e.g., camera, webcam, etc.), infrared, thermal (e.g., thermistors etc.), force, pressure, acoustic (e.g., microphone), ultrasonic, proximity, position, deformation, bending, direction, movement, velocity, rotation, gyroscope, Inertial Measurement Unit (IMU), and/or acceleration sensor(s). Sensors 110 may include geo-location sensors, such as a GPS sensor or other location sensors configured to determine the location of IHS 100 based on triangulation and network information. Various sensors, such as optical, infrared and sonar sensors, may be used in the detection of individuals in proximity to the IHS 100 and/or in other forms of user presence detection.

In some embodiments, IHS 100 may not include all components shown in FIG. 1. In other embodiments, IHS 100 may include other components in addition to those shown in FIG. 1. Furthermore, components illustrated as separate components in FIG. 1 may instead be integrated with other components, such that all or a portion of the operations executed by such components may instead be executed by the integrated component.

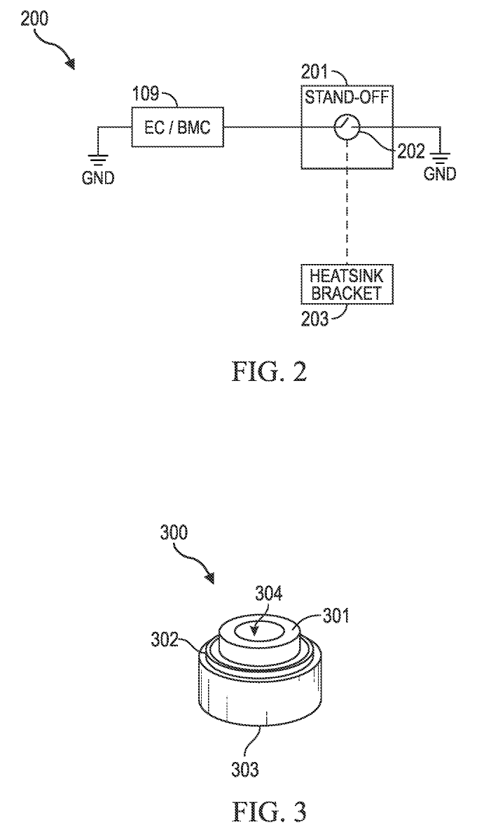

FIG. 2 is a diagram illustrating an example of a stand-off system for heatsink detection. In some embodiments, EC/BMC/CMC 109 is coupled to stand-off 201 via a GPIO pin. By default, stand-off 201 operates as an open circuit or loop. When an IHS component is coupled to stand-off 201 without a heatsink, the circuit stays open. When a component with a heatsink is coupled to stand-off 201, however, a heatsink bracket closes the loop and allows EC/BMC/CMC 109 to detect the presence of the heatsink by transmitting/receiving a signal via the GPIO pin.

To illustrate this, FIG. 3 is a diagram of an example of stand-off 300. In some embodiments, stand-off 300 has three portions, sections, rings, or parts, including: inner conductive ring 301, insulation ring 302, and outer conductive ring 303. Each of rings 301-303 may have a generally cylindrical form. As shown, insulation ring 302 has an inner surface coupled to an outer surface of inner conductive ring 301, and outer conductive ring 303 has an inner surface coupled to an outer surface of insulation ring 302. Inner conductive ring 301 is configured to receive a fastener via opening 304, which in some implementations may be threaded.

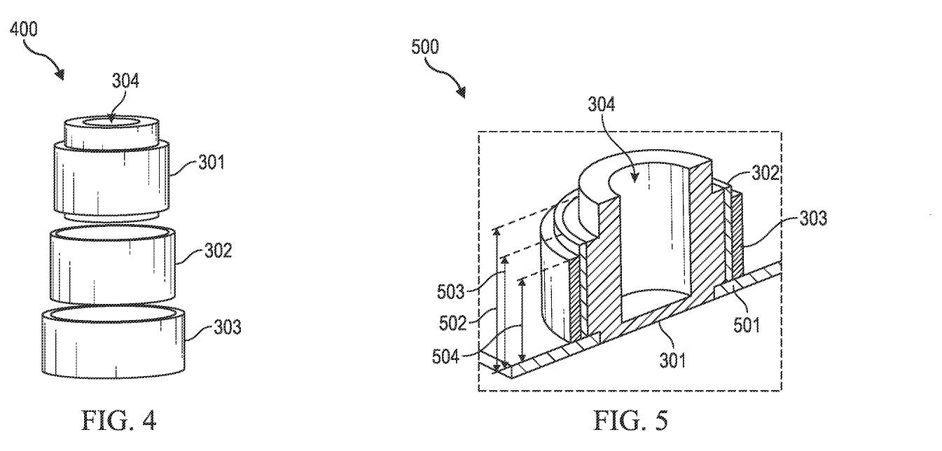

FIG. 4 shows an exploded view 400 of stand-off 301, with rings 301-303 decoupled from each other for ease of visualization. FIG. 5 shows a cross-sectional view 500of stand-off 300 mounted or otherwise integrated into an IHS chassis, motherboard, or PCB 501. In some embodiments, inner conductive ring 301 may include a first portion having first height or length 502 and a second portion adjacent first portion having second height or length 503 smaller than first height or length 502, and where outer conductive ring 303 may have third height or length smaller 504 than second height or length 503. Moreover, insulation ring 302 may also have second height or length 503.

In various embodiments, inner conductive ring 301 and outer conductive ring 303 may be made of any conductive material, such as, for example: copper, steel, aluminum, or other suitable metals and alloys. These materials may be chosen for their excellent electrical conductivity, thermal, and/or mechanical properties, ensuring reliable electrical connections and structural integrity. Meanwhile, insulation ring 302 may be made of any electrically insulating material such as, for example: plastic, ceramic, rubber, or glass. These materials may be selected for their high electrical resistance and ability to withstand environmental conditions, preventing unwanted electrical conduction between the inner and outer conductive rings. In various embodiments, the choice of insulating material can also be influenced by factors such as thermal stability, mechanical strength, and ease of manufacturing, ensuring the overall effectiveness and durability of stand-off 300.

In various embodiments, inner conductive ring 301 is coupled to a ground terminal, and outer conductive ring 303 is coupled to a GPIO pin, as shown in FIG. 2, effectively operating as open circuit, loop, or switch 202. Alternatively, the configuration can be reversed, with the inner conductive ring 301 coupled to the GPIO pin and the outer conductive ring 303 coupled to the ground terminal, achieving the same detection functionality. This allows system 200 to detect the presence of a heatsink by monitoring the electrical connection between the inner and outer conductive rings 301 and 303 of stand-off 300. When a heatsink is installed, it bridges the connection between the inner and outer rings, closing the electrical circuit and sending a signal to the GPIO pin.

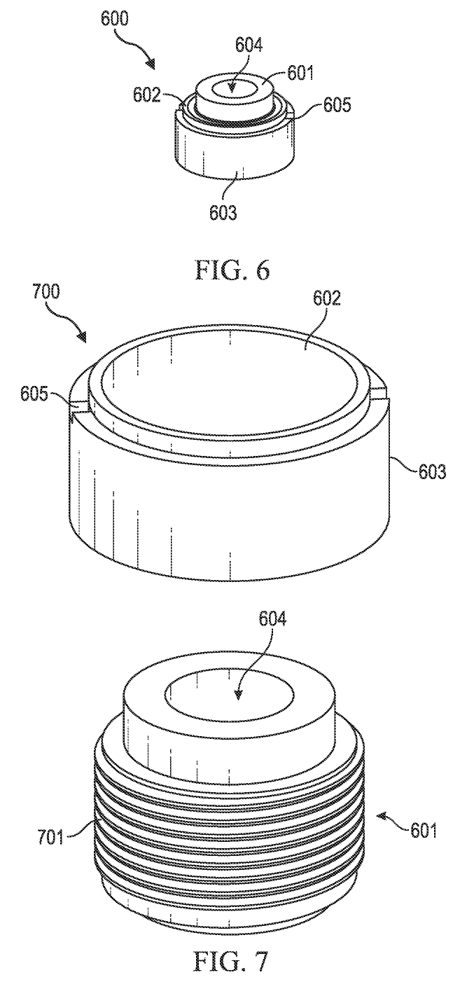

FIG. 6 is a diagram illustrating an example of another stand-off 600. In some embodiments, stand-off 600 has three portions, sections, rings, or parts, including: inner conductive ring 601, insulation ring 602, and outer conductive ring 603. Each of rings 601-603 may have a generally cylindrical form, and the outer surface of first conductive ring 601 may be threaded, as part of a screwed-on sleeve design for additional flexibility of manufacturing and assembly.

As assembled, insulation ring 602 has its inner surface screwed onto the threaded, outer surface of inner conductive ring 601, and outer conductive ring 603 has an inner surface coupled to an outer surface of insulation ring 602. Inner conductive ring 601 is configured to receive a fastener via opening 604, which in some implementations may also be threaded.

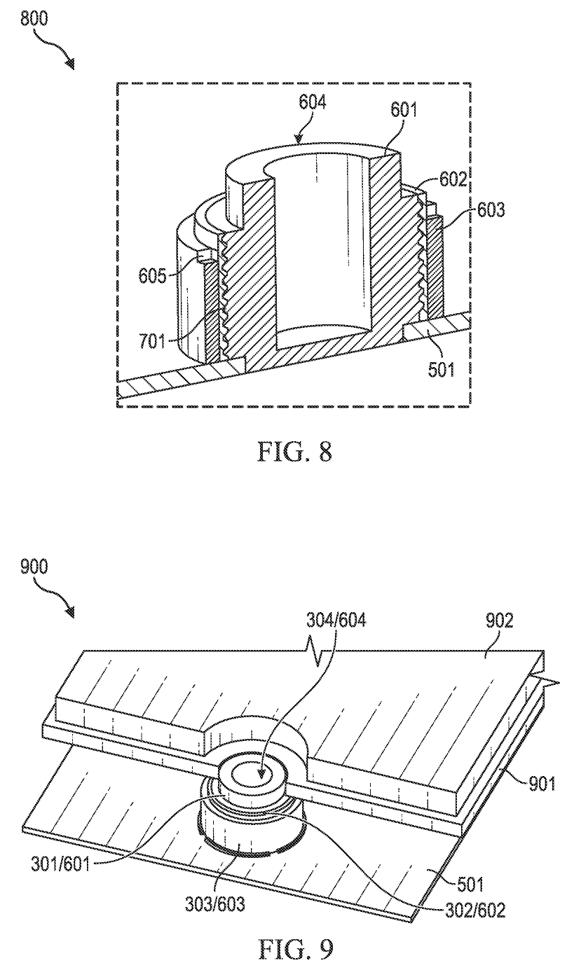

FIG. 7 shows an exploded view 700 of stand-off 601 with rings 601-603 decoupled from each other for ease of visualization, such that inner conductive ring 601 is unscrewed from insulation ring 602. FIG. 8 shows a cross-sectional view 800 of stand-off 300 mounted or otherwise integrated into an IHS chassis, motherboard, or PCB 501.

FIG. 9 shows diagram 900 of an example of stand-off 300/600 configured to receive IHS component 902 mounted on PCB, card, adapter, or daughterboard 901. In various embodiments, stand-off 300/600 may be part of PCB, chassis, or motherboard 501 of IHS 100, and at least a portion of PCB 901 of component 902 may be vertically supported by stand-off 300/600 upon installation, such that a fastener introduced into opening 304/604 may keep component 902 in a desired place or physical configuration. In some cases, vertical support may be provided, at least in part, by at least semi-circular portion of inner conducting ring 301/604’s and/or insulation ring 302’s second height, which operate as a rest or platform for PCB 901. Additionally, or alternatively, a difference between the first and second heights or lengths may be selected to be equal or proportional to the thickness of PCB 901.

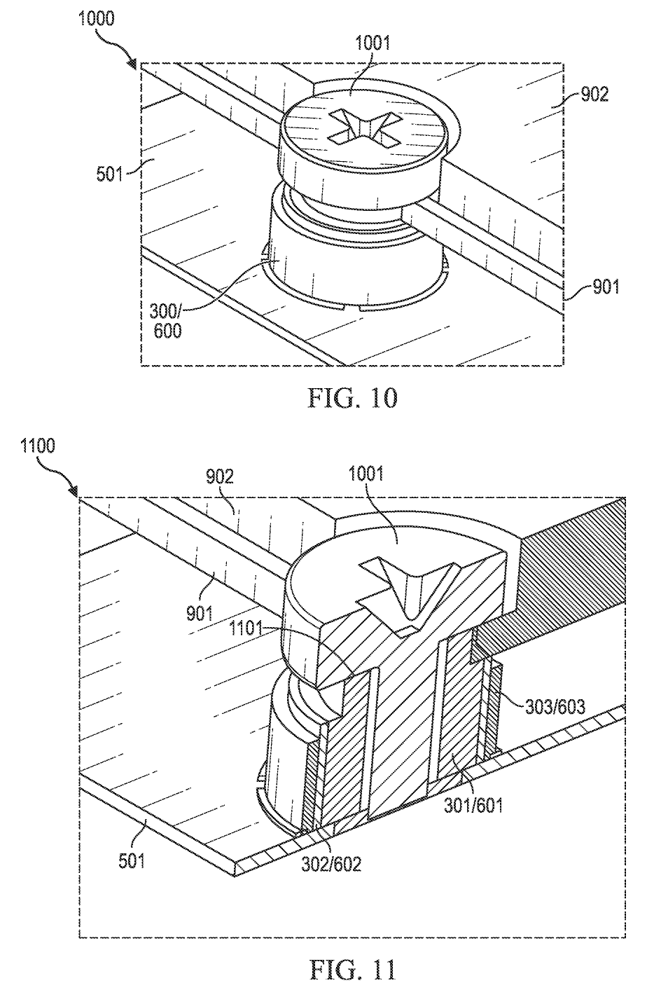

FIG. 10 shows diagram 1000 of an example of IHS component 902 fastened onto stand-off 300/600 without a heatsink. In some embodiments, fastener 1001 may be a screw, or the like, which holds PCB 901 in place with respect to motherboard 501. FIG. 11 is a cross-section of IHS component 902 fastened onto stand-off 300/600, still without a heatsink. As shown, fastener 1001 makes contact against surface 1101 of inner conductive ring 301/601 but it does not contact outer conductive ring 303/603, therefore leaving switch 202 open.

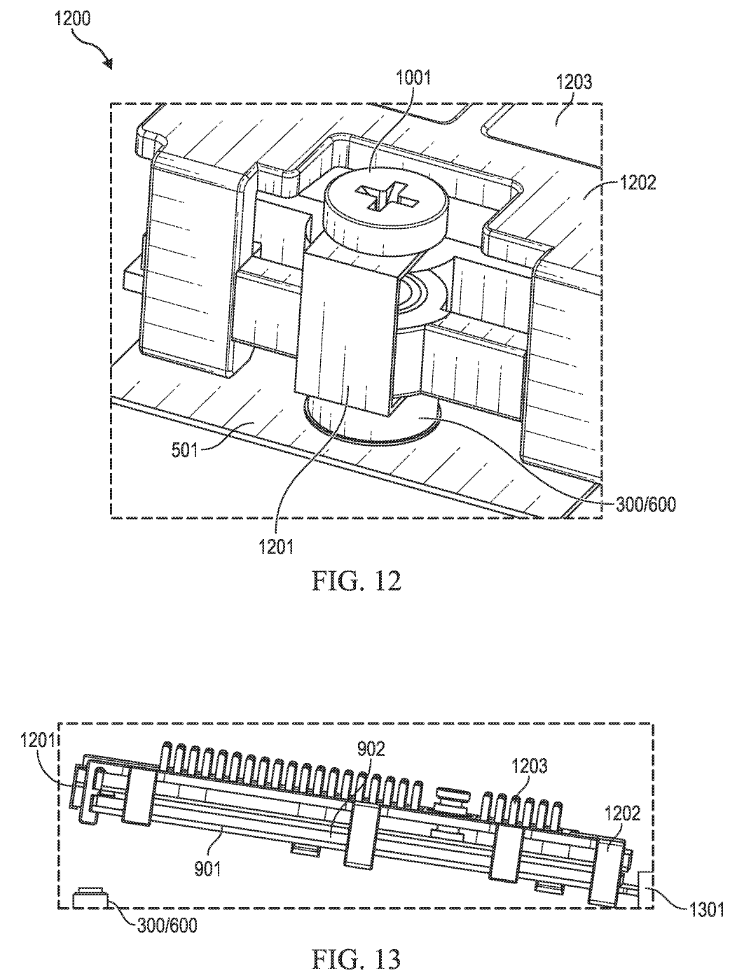

FIG. 12 shows diagram 1200 of an example of IHS component 902 and heatsink 1203 fastened onto stand-off 300/600. In some embodiments, heatsink 1203 may be thermally coupled to component 902 (not visible), and clip 1202 may keep heatsink 1203 attached to PCB 901 over component 902. Moreover, diagram 1200 shows conductive bracket 1201 disposed between fastener 1001 and stand-off 300/600. In various embodiments, bracket 1201 may close switch 202 between inner conductive ring 301/601 and outer conductive ring 303/603 to indicate, to EC/BMC/CMC 109 via a GPIO pin, the presence of heatsink 1203 coupled to component 902.

FIG. 13 depicts diagram 1300 of IHS component 902 and heatsink 1203 being coupled to stand-off 300/600. In some embodiments, a heatsink assembly including heatsink 1202, clip 1203, and conductive bracket 1201 may be coupled to a component assembly including component 902 on PCB 901, and the entire system may be coupled to stand-off 300/600, sometimes against a pivot point or fixed portion 1301 (e.g., another stand-off) of the IHS’s chassis or motherboard 501.

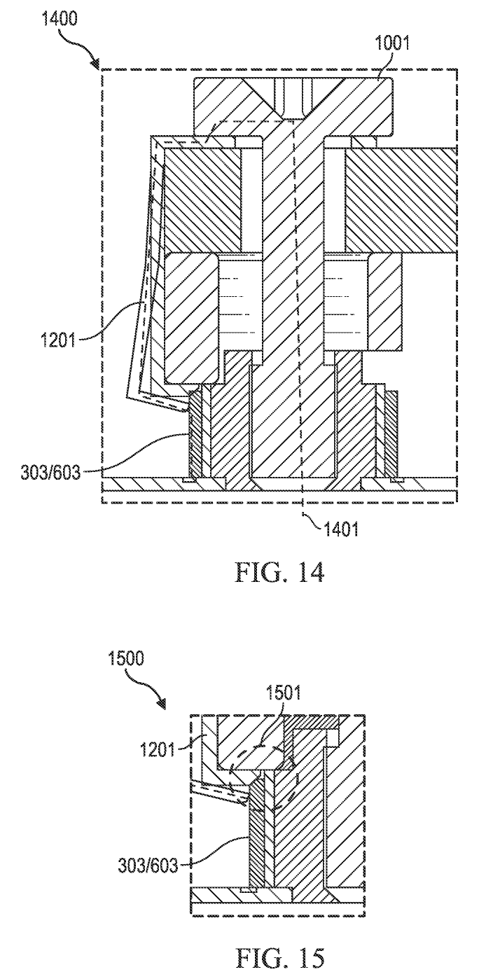

FIG. 14 shows a cross-section view 1400 of IHS component 902 and heatsink 1203 fastened onto stand-off 300/600. In some embodiments, electrical switch or loop 202 is closed by the presence of conductive bracket 1201 electrically coupling inner conductive ring 301/601 to outer conductive ring 303/603, which allows current 1401 to flow.

In this implementation, when heatsink 1202 is installed, electrical current 1401 flows from GPIO pin or terminal 1402 through outer conductive ring 303/603, conductive bracket 1201, fastener 1001, and inner conductive ring 301/601 to a ground terminal. In various embodiments, conductive bracket 1201 may be configured so that its bottommost portion applies lateral mechanical pressure or force against outer conductive ring 303/603.

Meanwhile, FIG. 15 shows a cross-section view 1500 of bracket 1201 coupled to outer conductive ring 303/603 of stand-off 300/600. In this case, the meeting edges of bracket 1201 and outer conductive ring 303/603 may be chamfered at selected angles (e.g., 45 degrees, 60 and 30 degrees, etc.), as shown in contact area 1501, to help align or slide the various surfaces involved.

As such, systems and methods described herein may include a stand-off configured to receive an IHS component and a bracket that closes an electrical circuit via the stand-off, enabling detection of a heatsink. In various embodiments, these systems and methods may eliminate the need for multiple connection points on the motherboard, saving valuable PCB space.

The stand-off may may include an inner conductive ring, an insulation ring, and an outer conductive ring. When the heatsink is installed, the bracket may bridge the inner and outer rings, completing the circuit and sending a signal to the EC/BMC/CMC. This allows remote heatsink detection, improving system reliability, streamlining debugging, and enhancing thermal management by preventing component overheating and performance degradation.

The stand-off design may integrate an inner conductive ring, insulation ring, and outer conductive ring, which together form a detection circuit closed by a conductive bracket when the heatsink is installed. This configuration may provide efficient and reliable heatsink detection in an IHS. The inner conductive ring may secure a fastener that couples the IHS component to the stand-off, while the insulation ring may electrically isolate the inner and outer conductive rings. When the bracket bridges the outer ring, the circuit completes, allowing the stand-off to signal the presence of the heatsink.

By consolidating the detection mechanism into a single stand-off, these systems and methods may save PCB space and enable remote heatsink detection. These embodiments may also increase system reliability, reduce debugging time, and improve thermal management by automatically identifying heatsink installation, preventing potential overheating and performance issues. Moreover, these systems and methods may eliminate manual verification, reduce maintenance effort, and promote proper heatsink installation. The space-efficient stand-off design may integrate the detection mechanism into a single PCB location, simplifying board layout and improving overall thermal management, system reliability, and longevity.

To implement various operations described herein, computer program code (i.e., program instructions for carrying out these operations) may be written in any combination of one or more programming languages, including an object-oriented programming language such as Java, Smalltalk, Python, C++, or the like, conventional procedural programming languages, such as the “C” programming language or similar programming languages, or any of machine learning software. These program instructions may also be stored in a computer readable storage medium that can direct a computer system, other programmable data processing apparatus, controller, or other device to operate in a particular manner, such that the instructions stored in the computer readable medium produce an article of manufacture including instructions which implement the operations specified in the block diagram block or blocks.

Program instructions may also be loaded onto a computer, other programmable data processing apparatus, controller, or other device to cause a series of operations to be performed on the computer, or other programmable apparatus or devices, to produce a computer implemented process such that the instructions upon execution provide processes for implementing the operations specified in the block diagram block or blocks.

Modules implemented in software for execution by various types of processors may, for instance, include one or more physical or logical blocks of computer instructions, which may, for instance, be organized as an object or procedure. Nevertheless, the executables of an identified module need not be physically located together but may include disparate instructions stored in different locations which, when joined logically together, include the module and achieve the stated purpose for the module. Indeed, a module of executable code may be a single instruction, or many instructions, and may even be distributed over several different code segments, among different programs, and across several memory devices.

Similarly, operational data may be identified and illustrated herein within modules and may be embodied in any suitable form and organized within any suitable type of data structure. Operational data may be collected as a single data set or may be distributed over different locations including over different storage devices.

Reference is made herein to “configuring” a device or a device “configured to” perform some operation(s). This may include selecting predefined logic blocks and logically associating them. It may also include programming computer software-based logic of a retrofit control device, wiring discrete hardware components, or a combination thereof. Such configured devices are physically designed to perform the specified operation(s).

Various operations described herein may be implemented in software executed by processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs.

As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

1. An assembly, comprising:
a stand-off configured to receive an Information Handling System (IHS) component; and
a bracket configured to close an electrical circuit via the stand-off, wherein the electrical circuit is usable to determine whether a heatsink is present.

2. The assembly of claim 1, wherein the component comprises a device disposed on a Printed Circuit Board (PCB), and wherein the PCB is mountable on the stand-off.

3. The assembly of claim 1, wherein the device comprises at least one of: a processor, a memory, a storage device, a system-on-chip (SoC), a fan, a battery, or a power supply.

4. The assembly of claim 1, wherein the stand-off comprises:
an inner conductive ring;
an insulation ring having an inner surface coupled to an outer surface of the inner conductive ring; and
an outer conductive ring having an inner surface coupled to an outer surface of the insulation ring.

5. The assembly of claim 4, wherein to close an electrical circuit, the bracket electrically couples the inner conductive ring to the outer conductive ring.

6. The assembly of claim 4, wherein the inner conductive ring is coupled to a ground terminal, and wherein the outer conductive ring is coupled to a General Purpose Input/Output (GPIO) pin of an Embedded Controller (EC), Baseboard Management Controller (BMC), or Chassis Management Controller (CMC).

7. The assembly of claim 4, wherein the outer conductive ring and the insulation ring form a sleeve that screws onto the inner conductive ring.

8. The assembly of claim 4, wherein the bracket electrically couples the inner ring to the outer ring via a fastener, the fastener configured to mechanically couple the component to the stand-off.

9. The assembly of claim 4, wherein the inner conductive ring is taller than the outer conductive ring.

10. The assembly of claim 4, wherein the inner conductive ring comprises a first portion having a first height and a second portion having a second height smaller than the first height, wherein the insulation ring has the second height, and wherein the outer conductive ring has a third height smaller than the second height.

11. The assembly of claim 4, wherein the bracket is configured to apply pressure against the outer conductive ring.

12. The assembly of claim 4, wherein an edge of the bracket is chamfered to match an edge of the outer conductive ring.

13. A stand-off, comprising:
an inner conductive ring configured to receive a fastener that couples an Information Handling System (IHS) component to the stand-off;
an insulation ring coupled to the inner conductive ring; and
an outer conductive ring coupled to the insulation ring, the outer conductive ring coupled to a conductive bracket configured to close an electrical circuit between the inner conductive ring and the outer conductive ring to indicate the presence of a heatsink.

14. The stand-off of claim 13, wherein the outer conductive ring and the insulation ring form a sleeve that screws onto the inner conductive ring.

15. The stand-off of claim 13, wherein the inner conductive ring is taller than the outer conductive ring.

16. The stand-off of claim 13, wherein the inner conductive ring comprises a first portion having a first height and a second portion having a second height smaller than the first height, and wherein the outer conductive ring has a third height smaller than the second height.

17. The stand-off of claim 13, wherein the bracket is configured to apply a force against the outer conductive ring.

18. The stand-off of claim 13, wherein an edge of outer conductive ring is chamfered to match an edge of the bracket.

19. A method, comprising:
transmitting a signal via a General-Purpose Input/Output (GPIO) pin to a stand-off of an Information Handling System (IHS), wherein the stand-off enables an IHS component to be fastened onto the IHS; and
determining whether a heatsink is coupled to the IHS component based, at least in part, upon whether a bracket closes an electrical circuit provided by the stand-off.

20. The method of claim 19, wherein the stand-off comprises: an inner conductive ring, an insulation ring coupled to the inner conductive ring, and an outer conductive ring coupled to the insulation ring, and wherein to close the electrical circuit, the bracket couples the inner ring to the outer ring.
